(19) United States
(12) Patent Application Publication
(10) Pub. No.: US 2006/0183026 A1
(43) Pub. Date: Aug. 17, 2006

(54) Masking for wafer fabrication

(76) Inventors: Ling Tseng Tee, Singapore (SG); Lian Soon Peh, Singapore (SG)

Correspondence Address: HARNESS, DICKEY, & PIERCE, P.L.C, 7700 BONHOMME, STE 400, ST. LOUIS, MO, 63105, US

(21) Appl. No.: 11/059,788

(22) Filed: Feb. 17, 2005

(51) Int. Cl. G03F 1/00; G03C 5/00

(52) U.S. Cl. 430/5; 430/30

(57) ABSTRACT

The invention comprises a method of preparing masks for wafer fabrication comprising the steps of determining the length of the required mask image size along one axis, determining the length of the required mask image size along a second axis, comparing the length of the required mask image size to data related to the standard image field size, and applying a one dimension rule to extend the standard image field size along one dimension if needed.

### BACKGROUND OF THE INVENTION

1. Field of the Invention

The present invention relates to masks for use in wafer fabrication and in particular to masks for etch sizes greater than that available from current machinery.

2. Description of the Prior Art

In wafer fabrication during some etching processes masking layers are placed above the wafer and the wafer then exposed to light to transfer the mask onto the wafer surface. During the photolithography process, a set of masks is required to define the openings in the oxide layer through which the various diffusions are made, the windows through which the metal connection contacts are formed, and the pattern in which the desired metal interconnections are formed. The masks are either emulsion on glass for an etched thin film of chromium or iron oxide on glass. Masks are produced by photographic reduction from large scale layouts. Masks can also be used in the manufacture of thin film circuits in order to define the pattern of material deposited as a thin film by vacuum evaporation onto a substrate.

Because masks are printed and they are limited by the size this causes problems when the wafer is larger than the field size of a mask.

### BRIEF SUMMARY OF THE INVENTION

Accordingly to the present invention there is provided a method of preparing masks for wafer fabrication comprising the steps of determining the length of the required mask image size along one axis, determining the length of the required mask image size along a second axis, comparing the length of the required mask image size to data related to the standard image field size, and applying a one dimension rule to extend the standard image field size along one dimension if needed.

Preferably the invention further comprises the step of applying indicia to the image masks if more than one mask is required.

Preferably the invention further comprises the step of comparing the length of required mask image size along one axis to the shorter side of standard image size.

Preferably the invention further comprises the step of comparing the length of the longer required mask image size along a second axis to the standard image size.

Preferably the invention further comprises the step of setting the required mask image size along one axis to shorter side of the standard image mask if the length of the required mask image size along one axis is less than the length of the shorter side of the standard image mask.

Preferably the invention further comprises the step of setting the required mask image size along a second axis to the longer side of the standard image mask if the length of the required mask image size along a second axis is less than the length of the longer side of the standard image mask.

Preferably the invention further comprises the step of setting the required mask image size along one axis to twice the longer side of the standard image mask if the length of the other side is greater than the length of the longer side of the standard image.

Preferably the invention farther comprises the step of setting the required mask image size along one axis to the longer side of the standard image mask if the length of the required mask image size along one axis is greater than the length of the shorter side of the standard image mask and less than the length of the longer side of the standard image mask.

Preferably the invention further comprises the step of setting the required mask image size along a second axis to the shorter side of the standard image mask if the length of the required mask image size along a second axis is less than the length of the shorter side of the standard image mask.

Preferably the invention further comprises the step of setting the required mask image size along a second axis to twice the shorter side of the standard image mask if the length of the required mask image size along a second axis is greater than the length of the shorter side of the standard image mask.

Preferably the invention further comprises the step of setting the required mask image size along one axis to twice the longer side of the standard image mask and the required mask image size along a second axis to the shorter side of the image mask if the required mask image size along one axis is longer than the longer side of the standard image mask and the other side is shorter than the shorter side of the standard image mask.

Preferably the invention further comprises the step of setting the required mask image size along one axis to twice the shorter side of the standard image mask if the length of the required mask image size along one axis is longer than the longer side of the standard image mask but less than twice the length of the shorter side and setting the required mask image size along a second axis to the longer side if the length of the required mask image size along a second axis is greater than the length of the shorter side and less than the length of the longer side of the standard image mask.

### BRIEF DESCRIPTION OF THE SEVERAL VIEWS OF THE DRAWINGS

The invention will be further described by way of example only and without intending to be limiting with reference to the following drawings, wherein:

FIG. 1 shows two masked images one above the other.

FIG. 2a shows a first mask with an overlap area defined.

FIG. 2b shows a second mask with an overlap area defined.

FIG. 3 shows a wafer on which it is desired to apply the mask.

### DETAILED DESCRIPTION OF THE INVENTION

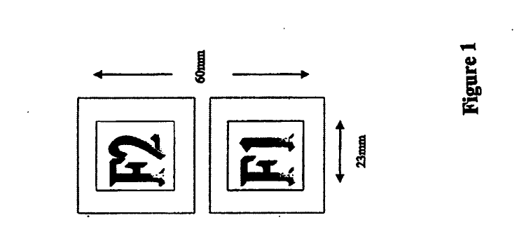

Current devices for producing masks have limited mask output sizes, for example the maximum image field size of a mask may be 26 mm by 33 mm. To produce a mask with an image field size that is bigger than produced with a current device a one dimension rule is applied. Using this rule the mask image is extended along one dimension only. If more than one mask is produced that the masks are then laid side by side with an overlap above the wafer. The one dimension rule means that whichever length of the required image is longer will become the multiple of one axis and the shorter length will be the other axis. For example, if the allowed image field size is 26 mm by 33 mm and a required mask size is 23 mm by 60 mm the X axis will be the 23 mm axis and the Y axis will be the 60 mm axis. If however, the required image size is 30 mm by 40 mm then the X axis will be the 40 mm and the Y axis will be 30 mm. This way the maximum image size is twice one of the axes by the other regardless of which axis is the longer one. This example is illustrated in FIG. 1 where two masks are provided to provide an image size of 23 mm by 60 mm.

Another way of expressing the one dimension rule is to determine size of required image. This can be done using the following logic;

Set A equal to the size in the one direction.

Set B equal to the size in the other direction.

The standard image size is X by Y (where X is less than Y).

(a) If A is less than or equal to X set A direction to X-axis.
(b) If A is greater than X check if A is greater than Y
(c) If A is less than Y set A direction to Y-axis

If A is greater than Y check B.
(d) If B is less than X set B to X-axis.
(e) If B is greater than X but less than Y set B to X-axis.
(f) If B is greater than Y—unable to mask.

This provides five cases. In the first case the A dimension is less than the shortest dimension of the image field size (denoted X-size for clarity) the A dimension can be aligned with the X-axis. The B dimension is automatically set to the Y-axis and can be more than one image as required extending in the Y-direction.

### EXAMPLES

For the following examples the standard X and Y sizes are set to:

X size=10 mm

Y size=20 mm
1. A=7 mm. B=7 mm.

A will be set on X axis and B will be set on the Y axis.
2. A=9 mm. B=15 mm.

A will be set on the X axis and B will be set on the Y axis.
3. A=8 mm. B=23 mm.

A is set on the X-axis and B will be set on the Y axis. In this case two masks will be required in the Y direction.

In the second, third, fourth and fifth cases the length of the image in the A direction is greater than the shortest dimension of the image field size. The three cases the A dimension is greater than the longer length and in the other case the A dimension is less than the longer length.

In the second case the length of the image in the A direction is less than the Y size. The A direction is then set to the Y-axis. The length of the image in the B direction is then considered if this length is less than twice the length of the X size the B direction is set to the X-axis. If the Y length is more than twice the X-length the lengths of the two sides of the image (A and B) should be compared and the shorter side be set to the X-direction.

### EXAMPLES

Again for these examples the X size is 10 mm and the Y size is 20 mm.
1. A=15 mm. B=17 mm.

A will be set on the Y axis and B will be set as two times the X-axis.
2. A=15 mm. B=7 mm.

A will be set on the Y axis and B will be set on the X-axis.

In the third, fourth and fifth cases the length of the image in the A direction is greater than the Y size. The A direction is then set to the Y-axis. The length of the image in the B direction is then considered.

If the length of the image in the B direction is less than the X-size the B direction is set to the X-axis.

### EXAMPLE

X=10 mm. Y=20 mm.

A=30 mm. B=7 mm.

Set A to two times the Y size on the Y-axis and B to the X-axis.

If the length of the image in the B direction is greater than the X size but less than the Y size set B to the Y-axis and A to the X-axis.

### EXAMPLE

X=26 mm. Y=33 mm.

A=50 mm. B=30 mm.

Set A to two times the X size on the X-axis and B to the Y-axis.

If the length of the image in the B direction is greater than the Y dimension then the image is too large to mask.

It should be noted that the above example lengths are examples only and not intended to be limiting.

The above describes one application of the one dimension rule—different implementations may be used.

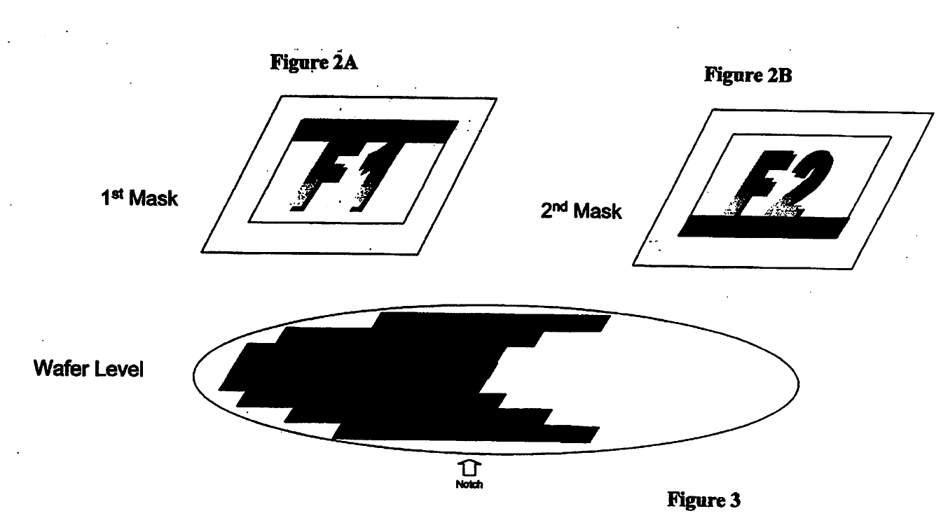

To align the wafers the mask layers are provided with indicators so that the mask layers can be overlapped above the wafers. FIGS. 2a and 2b show a first mask and a second mask. The grey area 1 at the top of the first mask is overlapped with the grey area 2 at the bottom of the second mask when the masks are aligned above the wafer. Indications are provided on the masks so that they are correctly aligned over the wafer.

In use the number and orientation of the masks is determined. The masks are then printed and the first mask is aligned to print down onto the wafer. In this step the orientation of the mask above the wafer is determined and the location of mask above the wafer is determined. The first mask is then printed down onto the wafer. Following this the second mask is aligned and will print down onto the wafer. This allows a larger potential print down area on a wafer than previously provided by a single mask. The indicators on the masks assist in correctly aligning and orientating the masks. Correctly locating the masks above the wafer can maximise the number of dies that can be formed on a wafer.

FIG. 3 shows a wafer which is as required to use a mask. The grey areas on the wafer show the dies that are about to be masked. Using the invention more than one mask can be aligned over the wafer to provide a greater area than was previously able to be provided with current layouts. The advantage of the present invention is that circuit design size layouts now have greater flexibility and are not limited to the printout size of mask machines.

The foregoing describes the invention including preferred forms thereof. Alterations and modifications as will be obvious to those skilled in the art are intended to be incorporated in the scope hereof as defined by the accompanying claims.

We claim

1. A method of preparing masks for wafer fabrication comprising the steps of,
determining the length of the required mask image size along one axis,
determining the length of the required mask image size along a second axis,
comparing the length of the required mask image size to data related to the standard image field size,
applying a one dimension rule to extend the standard image field size along one dimension if needed, and
applying the maximum number of masks to be used.

2. A method of preparing masks for wafer fabrication as claimed in claim 1 further comprising the step of applying indicia to the image masks if more than one mask is required.

3. A method of preparing masks for wafer fabrication as claimed in claim 1 further comprising the step of comparing the length of required mask image size along one axis to the shorter side of standard image size.

4. A method of preparing masks for wafer fabrication as claimed in claim 3 further comprising the step of comparing the length of the longer required mask image size along a second axis to the standard image size.

5. A method of preparing masks for wafer fabrication as claimed in claim 4 further comprising the step of setting the required mask image size along one axis to shorter side of the standard image mask if the length of the required mask image size along one axis is less than the length of the shorter side of the standard image mask.

6. A method of preparing masks for wafer fabrication as claimed in claim 5 further comprising the step of setting the required mask image size along a second axis to the longer side of the standard image mask if the length of the required mask image size along a second axis is less than the length of the longer side of the standard image mask.

7. A method of preparing masks for wafer fabrication as claimed in claim 5 further comprising the step of setting the required mask image size along one axis to twice the longer side of the standard image mask if the length of the other side is greater than the length of the longer side of the standard image.

8. A method of preparing masks for wafer fabrication as claimed in claim 4 further comprising the step of setting the required mask image size along one axis to the longer side of the standard image mask if the length of the required mask image size along one axis is greater than the length of the shorter side of the standard image mask and less than the length of the longer side of the standard image mask.

9. A method of preparing masks for wafer fabrication as claimed in claim 8 further comprising the step of setting the required mask image size along a second axis to the shorter side of the standard image mask if the length of the required mask image size along a second axis is less than the length of the shorter side of the standard image mask.

10. A method of preparing masks for wafer fabrication as claimed in claim 8 further comprising the step of setting the required mask image size along a second axis to twice the shorter side of the standard image mask if the length of the required mask image size along a second axis is greater than the length of the shorter side of the standard image mask.

11. A method of preparing masks for wafer fabrication as claimed in claim 4 further comprising the step of setting the required mask image size along one axis to twice the longer side of the standard image mask and the required mask image size along a second axis to the shorter side of the image mask if the required mask image size along one axis is longer than the longer side of the standard image mask and the other side is shorter than the shorter side of the standard image mask.

12. A method of preparing masks for wafer fabrication as claimed in claim 4 further comprising the step of setting the required mask image size along one axis to twice the shorter side of the standard image mask if the length of the required mask image size along one axis is longer than the longer side of the standard image mask but less than twice the length of the shorter side and setting the required mask image size along a second axis to the longer side if the length of the required mask image size along a second axis is greater than the length of the shorter side and less than the length of the longer side of the standard image mask.

13. A method of mask print down for wafer fabrication comprising the steps of determining the number or masks to be used, determining the orientation of the masks on the wafer and determining the location of a first mask print down on the wafer.

14. A method of mask print down for wafer fabrication as described in claim 13 further comprising the step of printing down the image from a first wafer and then printing down the image from a second wafer.
